(19) United States
(12) Patent Application Publication
(10) Pub. No.: US 2017/0236857 A1
(43) Pub. Date: Aug. 17, 2017

(54) PHOTOELECTRIC CONVERSION ARRAY SUBSTRATE, ITS MANUFACTURING METHOD, AND PHOTOELECTRIC CONVERSION DEVICE

(71) Applicant: BOE TECHNOLOGY GROUP CO., LTD., Beijing (CN)

(72) Inventor: Qianqian BU, Beijing (CN)

(73) Assignee: BOE TECHNOLOGY GROUP CO., LTD., Beijing (CN)

(21) Appl. No.: 15/106,137

(22) PCT Filed: Oct. 19, 2015
(86) PCT No.: PCT/CN2015/092197

§ 371 Date: Jun. 17, 2016

(30) Foreign Application Priority Data
Jun. 30, 2015 (CN) 201510373175.1

(51) Int. Cl. H01L 27/146

(52) U.S. Cl. CPC H01L 27/14607; H01L 27/14643; H01L 27/14612; H01L 27/14629; H01L 27/1462; H01L 27/14689; H01L 27/14692

(57) ABSTRACT

The present disclosure provides a photoelectric conversion array substrate, its manufacturing method and a photoelectric conversion device. The photoelectric conversion array substrate includes a TFT arranged on a base substrate and a photodiode connected to the TFT. A photosensitive surface of the photodiode is a convex surface.

### CROSS-REFERENCE TO RELATED APPLICATION

The present application claims a priority of the Chinese Patent Application No. 201510373175.1 filed on Jun. 30, 2015, which is incorporated herein by reference in its entirety.

### TECHNICAL FIELD

The present disclosure relates to the field of digital X-ray image detection, in particular to a photoelectric conversion array substrate, its manufacturing method, and a photoelectric conversion device.

### BACKGROUND

X-ray detection has been widely used in such fields as medical treatment, security, nondestructive testing and scientific research, and plays an increasingly important role in the national economy and the people's livelihood. Currently, an X-ray digital radiography (DR) detection technique developed in the late 1990s is commonly used. Depending on electronic conversion modes, the X-ray DR detection technique may include a direct DR detection technique and an indirect DR detection technique.

The indirect DR detection technique has been widely used nowadays due to such advantages as being mature, cost-effective and having excellent device stability. An array substrate for an X-ray detection device includes a thin film transistor (TFT) and a photodiode. When being irradiated by an X-ray, a scintillator layer and a phosphor layer of the array substrate convert X-ray photons into a visible light beam, and then the visible light beam is converted by the photodiode into an electric signal. The electric signal is read and outputted by the TFT, so as to acquire an image. As a key component of the array substrate, the photodiode determines the absorption efficiency of the visible light beams, and it may have a great influence on such indicators as an X-ray dose, a resolution of the resultant image and a response speed of the image.

However, in the array substrate of the conventional indirect X-ray detection device, a scattering phenomenon of the visible light beam may usually occur in the case that the visible light beam is converted by the photodiode into the electric signal, and the absorption efficiency of the visible light beam is relatively low, so the resultant image quality will be adversely affected. In order to ensure the image quality, it is usually required to increase the X-ray dose.

### SUMMARY

An object of the present disclosure is to provide a photoelectric conversion array substrate, its manufacturing method and a photoelectric conversion device, so as to increase the absorption efficiency of a photodiode for a visible light beam, thereby to improve the conversion efficiency of the photoelectric conversion array substrate for converting the visible light beam into an electric signal.

In one aspect, the present disclosure provides in some embodiments a photoelectric conversion array substrate, including a TFT arranged on a base substrate and a photodiode connected to the TFT. A photosensitive surface of the photodiode is a convex surface.

Alternatively, at least one of a portion of the base substrate corresponding to the photodiode, a portion of a gate insulating layer of the TFT corresponding to the photodiode, a portion of a drain electrode of the TFT corresponding to the photodiode, and a portion of a reflective electrode layer of the photoelectric conversion array substrate corresponding to the photodiode is of a convex structure, and the photodiode is formed on the convex structure so that the photosensitive surface of the photodiode forms the convex surface.

Alternatively, at least one of a P-type silicon layer, an N-type silicon layer, an I-type silicon layer and a transparent electrode of the photodiode is of a convex structure, so that the photosensitive surface of the photodiode forms the convex surface.

Alternatively, the reflective electrode layer and the drain electrode of the TFT form an integral structure, a portion of the integral structure corresponding to the photodiode is of a convex structure, and the photodiode is formed on the convex structure.

Alternatively, the reflective electrode layer is arranged between the drain electrode of the TFT and the photodiode, a portion of the reflective electrode layer corresponding to the photodiode is of a convex structure, and the photodiode is formed on the convex structure.

Alternatively, the photoelectric conversion array substrate includes the TFT formed on the base substrate, an insulating layer covering the base substrate provided with the TFT and including a via-hole at a position corresponding to the drain electrode of the TFT, the reflective electrode layer formed on the insulating layer and connected to the drain electrode through the via-hole, and the photodiode formed on the reflective electrode layer.

Alternatively, the photoelectric conversion array substrate further includes a scintillator layer and a phosphor layer capable of covering X-ray photons into a visible light beam, and the converted visible light beam is directed toward the photosensitive surface of the photodiode.

Alternatively, the convex surface is of a curvature radius of 1 to 10 μm.

Alternatively, the convex surface is of a curvature radius of 2 to 5 μm.

Alternatively, the convex surface is of a length of 2 to 10 μm, a width of 2 to 8 μm, and a height of 0.8 to 1.5 μm.

In another aspect, the present disclosure provides in some embodiments a photoelectric conversion device, including the above-mentioned photoelectric conversion array substrate.

In yet another aspect, the present disclosure provides in some embodiments a method for manufacturing a photoelectric conversion array substrate, including a step of forming on a base substrate a TFT and a photodiode connected to the TFT. A photosensitive surface of the photodiode is a convex surface.

Alternatively, the method further includes forming at least one of a portion of the base substrate corresponding to the photodiode, a portion of a gate insulating layer of the TFT corresponding to the photodiode, a portion of a drain electrode of the TFT corresponding to the photodiode, and a portion of a reflective electrode layer of the photoelectric conversion array substrate corresponding to the photodiode into a convex structure, and forming the photodiode on the convex structure; or forming at least one of a P-type silicon layer, an N-type silicon layer, an I-type silicon layer and a transparent electrode of the photodiode into a convex structure.

Alternatively, the step of forming the portion of the gate insulating layer of the TFT corresponding to the photodiode into the convex structure includes: forming an organic insulating film with an inorganic insulating material; coating a photoresist with a protrusion onto the organic insulating film at a position corresponding to the photodiode; and dry-etching the organic insulating film coated with the photoresist so as to obtain the gate insulating layer having the convex structure.

Alternatively, the organic insulating material is etched at a rate greater than the photoresist.

Alternatively, the method further includes steps of: forming an integral structure of the drain electrode of the TFT and the reflective electrode layer, a portion of the integral structure corresponding to the photodiode being of a convex structure; and forming the photodiode on the convex structure.

Alternatively, the method further includes steps of forming the reflective electrode layer having a convex structure on the drain electrode of the TFT, and forming the photodiode on the convex structure.

Alternatively, the method further includes a step of forming a PIN-type photodiode having a convex photosensitive surface on the base substrate provided with the TFT through an electroplating process.

Alternatively, the method includes steps of: providing the base substrate; forming the TFT and an insulating layer covering the TFT on the base substrate; forming a metal electrode layer with a protrusion on the insulating layer through an electroplating process; reserving the metal electrode layer at the protrusion and removing the metal electrode layer at the other regions; forming an N-type silicon layer, an I-type silicon layer and a P-type silicon layer sequentially on the metal electrode layer at the protrusion; and reserving the N-type silicon layer, the I-type silicon layer and the P-type silicon layer at the protrusion, and removing the N-type silicon layer, the I-type silicon layer and the P-type silicon layer at the other regions, so as to obtain the photodiode with a convex surface, the photodiode being connected to the drain electrode of the TFT via the metal electrode layer.

According to the embodiments of the present disclosure, the photosensitive surface of the photodiode on the photoelectric conversion array substrate is the convex surface, so as to improve the absorption efficiency of the photodiode for the light beams by converging the light beams and reducing a scattering phenomenon of the visible light beams, thereby to improve the conversion efficiency of the photoelectric conversion array substrate for converting the visible light beam into an electric signal. In addition, in the case that the photoelectric conversion array substrate is applied to an X-ray detection device, it is able to reduce an X-ray dose while ensuring the image quality.

### BRIEF DESCRIPTION OF THE DRAWINGS

FIGS. 1A-1I are schematic views showing a photoelectric conversion array substrate according to an embodiment of the present disclosure;

FIGS. 2A-2J are schematic views showing a method for manufacturing the photoelectric conversion array substrate according to an embodiment of the present disclosure; and

FIGS. 3A-3E are schematic views showing a method for manufacturing a PIN-type photodiode with a convex surface according to an embodiment of the present disclosure.

### REFERENCE SIGN LIST

1, 31 base substrate
2 gate metal layer
3 gate insulating layer
30 photoresist
4 semiconductor layer
5 conductor layer
6 source/drain metal layer
71, 34 N-type silicon layer
72, 35 I-type silicon layer
73, 36 P-type silicon layer
8 transparent electrode layer
9 first passivation layer
10 bias electrode layer
11 second passivation layer
32 insulating layer
33 metal electrode layer

### DETAILED DESCRIPTION OF THE EMBODIMENTS

The present disclosure will be described hereinafter in conjunction with the drawings and embodiments. The following embodiments are for illustrative purposes only, but shall not be used to limit the scope of the present disclosure.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “connect” or “connected to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

In an array substrate of a conventional indirect X-ray detection device, a scattering phenomenon of a visible light beam may usually occur in the case that the visible light beam is converted by a photodiode into an electric signal, and the absorption efficiency of the visible light beam is relatively low, so the resultant image quality will be adversely affected. In order to ensure the image quality, it is usually required to increase the X-ray dose. To overcome this drawback, the present disclosure provides in some embodiments a photoelectric conversion array substrate, its manufacturing method and a photoelectric conversion device, so as to improve the absorption efficiency of the photodiode for the light beams, thereby to improve the conversion efficiency of the photoelectric conversion array substrate for converting the visible light beam the electric signal. In addition, in the case that the photoelectric conversion array substrate is applied to the X-ray detection device, it is able to reduce the X-ray dose while ensuring the image quality.

### First Embodiment

The present disclosure provides in this embodiment a photoelectric conversion array substrate, including a TFT formed on a base substrate and a photodiode connected to the TFT. A photosensitive surface of the photodiode is a convex surface. The convex surface is capable of converging light beams and reducing a scattering phenomenon of the visible light beams, so as to improve the absorption efficiency of the photodiode for the light beams, thereby to improve the conversion efficiency of the photoelectric conversion array substrate for converting the visible light beam into an electric signal. In addition, in the case that the photoelectric conversion array substrate is applied to an X-ray detection device, it is able to reduce an X-ray dose while ensuring the image quality.

The photosensitive surface of the photodiode is a surface capable of absorbing a visible light beam. In the case that the visible light beam arrives at the photosensitive surface, an electron on a valance band may be excited by a photon having energy greater than or equal to bandgap energy, so as to absorb the energy of the photon and jump to a conduction band, thereby to generate a free electron-hole pair. Under the effect of a reversely-biased external electric field, the electron-hole pair is separated immediately into the electron and the hole which move in a junction toward its two ends respectively, so as to generate a current in an external circuit.

To be specific, the photodiode may be a PIN-type photodiode, which includes an N-type silicon layer, an I-type silicon layer arranged on the N-type silicon layer, a P-type silicon layer arranged on the I-type silicon layer, and a transparent electrode arranged on the P-type silicon layer. The photoelectric conversion array substrate in this embodiment includes the base substrate 1; a pattern of a gate metal layer 2 arranged on the base substrate 1 and including a gate electrode of the TFT; a gate insulating layer 3; a semiconductor layer 4; a source/drain metal layer 6, a pattern of which includes a source electrode and a drain electrode 61 of the TFT and a reflective electrode layer 62 connected to the drain electrode, the reflective electrode layer 62 being formed integrally with the drain electrode 61 or between the drain electrode 61 and the photodiode; an N-type silicon layer 71 arranged on the reflective electrode layer 62; an I-type silicon layer 72 arranged on the N-type silicon layer 71; a P-type silicon layer 73 arranged on the I-type silicon layer 72; a transparent electrode layer 8 arranged on the P-type silicon layer 73; a first passivation layer 9; a bias electrode layer 10 arranged on the first passivation layer 9 and connected to the transparent electrode layer 8 through a via-hole in the first passivation layer 9; and a second passivation layer 11.

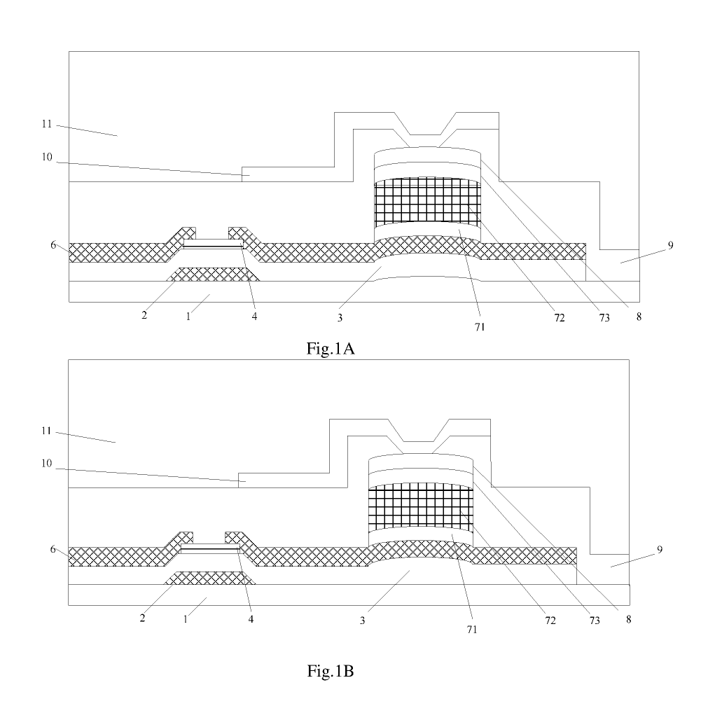

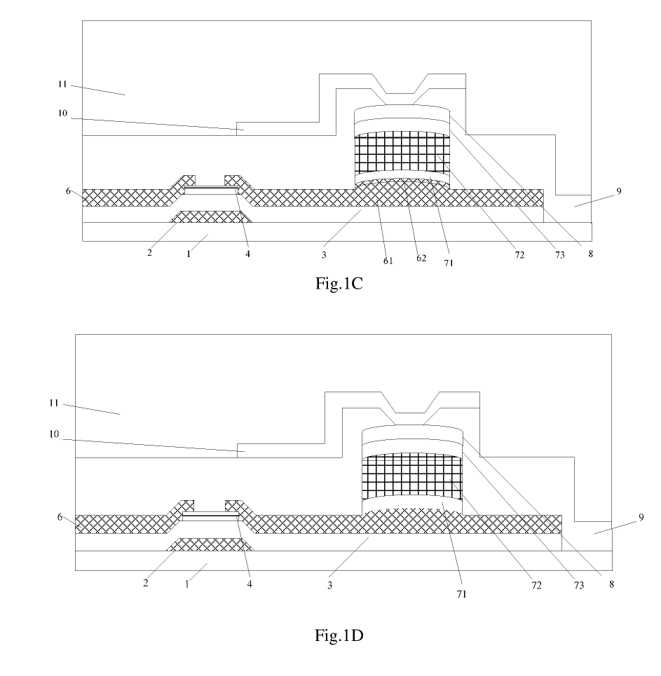

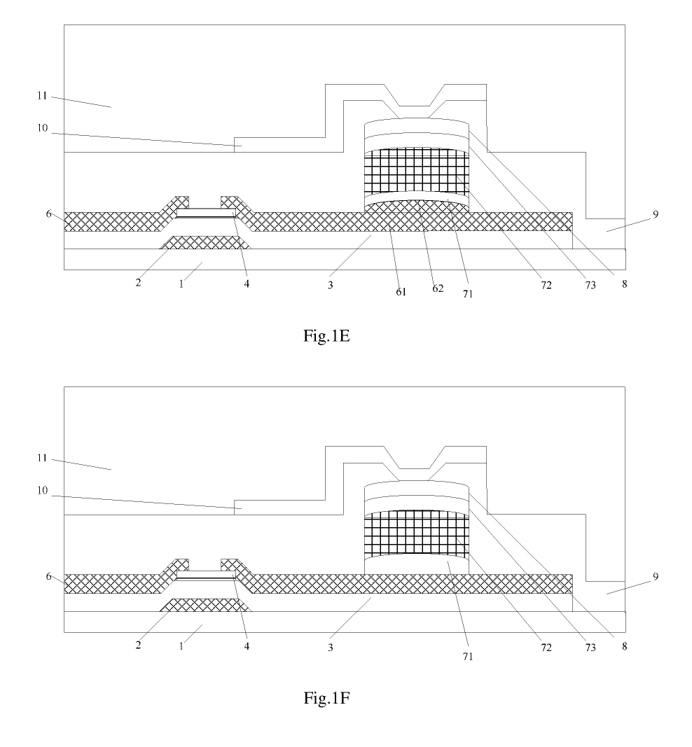

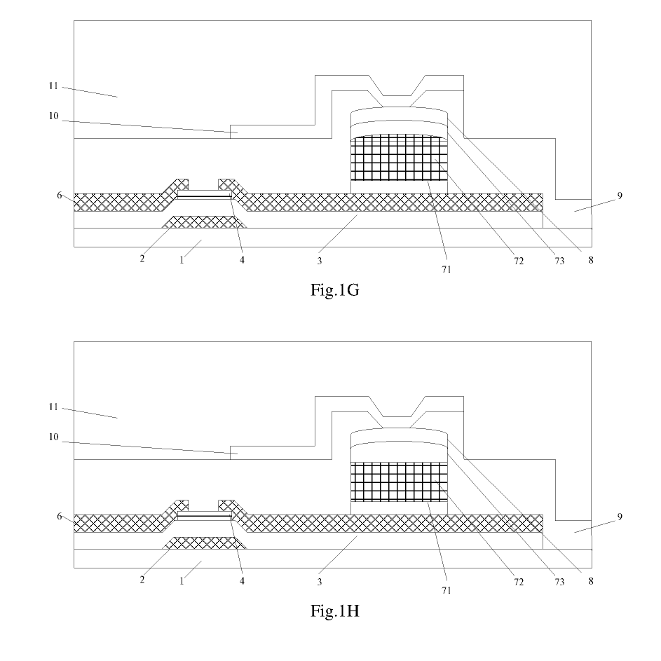

In order to form the photosensitive surface of the photodiode into the convex surface, in an alternative embodiment as shown in FIG. 1A, a portion of the base substrate 1 corresponding to the photodiode may be designed as a convex structure, so that the layers and the photodiode formed on the portion are each of a convex structure. The so-called “convex structure” refers to a structure whose end surface is a convex surface facing the visible light beam.

In order to form the photosensitive surface of the photodiode into the convex surface, in another embodiment as shown in FIG. 1B, a portion of the gate insulating layer 3 of the TFT corresponding to the photodiode may be designed as a convex structure, so that the layers and the photodiode formed on the portion are each of a convex structure.

In order to form the photosensitive surface of the photodiode into the convex surface, in yet another embodiment as shown in FIG. 1C, a portion of the drain electrode 61 of the TFT corresponding to the photodiode may be designed as a convex structure, so that the reflective electrode layer 62 and the photodiode formed on the portion are each of a convex structure.

In order to form the photosensitive surface of the photodiode into the convex surface, in still yet another embodiment as shown in FIG. 1D, the drain electrode of the TFT and the reflective electrode layer may form an integral structure, and a portion of the integral structure corresponding to the photodiode may be designed as a convex structure, so that the photodiode formed on the portion is of a convex structure.

In order to form the photosensitive surface of the photodiode into the convex surface, in still yet another embodiment as shown in FIG. 1E, a portion of the reflective electrode layer 62 corresponding to the photodiode may be designed as a convex structure, so that the photodiode formed on the reflective electrode layer 62 is of a convex structure.

Alternatively, as shown in FIG. 1F, the N-type silicon layer 71 of the photodiode may be of a convex structure, so that the photosensitive surface of the photodiode forms the convex surface.

Alternatively, as shown in FIG. 1G, the I-type silicon layer 72 of the photodiode may be of a convex structure, so that the photosensitive surface of the photodiode forms the convex surface.

Alternatively, as shown in FIG. 1H, the P-type silicon layer 73 of the photodiode may be of a convex structure, so that the photosensitive surface of the photodiode forms the convex surface.

Alternatively, as shown in FIG. 1I, the transparent electrode layer 8 of the photodiode may be of a convex structure, so that the photosensitive surface of the photodiode forms the convex surface.

Alternatively, apart from the TFT and the photodiode, the array substrate further includes: the first passivation layer formed on the TFT and the photodiode; a bias electrode and a signal line formed on the first passivation layer, the bias electrode being connected to the transparent electrode through the via-hole in the first passivation layer; and the second passivation layer formed on the bias electrode and the signal line.

In an alternative embodiment, the photoelectric conversion array substrate may include the TFT formed on the base substrate, an insulating layer covering the base substrate with the TFT and including a via-hole at a position corresponding to the drain electrode of the TFT, the reflective electrode layer formed on the insulating layer and connected to the drain electrode through the via-hole, and the photodiode formed on the reflective electrode layer.

The photoelectric conversion array substrate in this embodiment may be applied to an X-ray detection device. At this time, the photoelectric conversion array substrate further includes a scintillator layer and a phosphor layer capable of covering X-ray photons into a visible light beam, and the converted visible light beam is directed toward the photosensitive surface of the photodiode.

In order to improve the absorption efficiency of the photodiode for the light beams, theoretically, the larger a curvature of the convex surface, the better. However, due to the limitation of the manufacture process, the curvature radius of the convex surface may be 1 to 10 μm. Alternatively, the curvature radius of the convex surface may be 2 to 5 μm, and at this time, it is able to effectively improve the absorption efficiency of the photodiode for the light beams without increasing the production cost.

In an alternative embodiment, the convex surface may be of a length of 2 to 10 μm, a width of 2 to 8 μm, and a height of 0.8 to 1.5 μm. As compared with the conventional photodiode having a flat photosensitive surface, for the photodiode in this embodiment of the present disclosure, its absorption efficiency may be increased by more than 30%.

### Second Embodiment

The present disclosure provides in this embodiment a photoelectric conversion device, including the above-mentioned photoelectric conversion array substrate. The photoelectric conversion device may be an X-ray detection device. Through the photoelectric conversion array substrate, it is able to improve the conversion efficiency of the X-ray detection device to the visible light beams, thereby to reduce the X-ray dose while ensuring the image quality.

### Third Embodiment

The present disclosure provides in this embodiment a method for manufacturing a photoelectric conversion array substrate, including a step of forming on a base substrate a TFT and a photodiode connected to the TFT. A photosensitive surface of the photodiode is a convex surface. The convex surface is capable of converging light beams and reducing a scattering phenomenon of the visible light beams, so as to improve the absorption efficiency of the photodiode for the light beams, thereby to improve the conversion efficiency of the photoelectric conversion array substrate for converting the visible light beam into an electric signal. In addition, in the case that the photoelectric conversion array substrate is applied to an X-ray detection device, it is able to reduce an X-ray dose while ensuring the image quality.

To be specific, the method includes forming at least one of a portion of the base substrate corresponding to the photodiode, a portion of a gate insulating layer of the TFT corresponding to the photodiode, a portion of a drain electrode of the TFT corresponding to the photodiode, and a portion of a reflective electrode layer of the photoelectric conversion array substrate corresponding to the photodiode into a convex structure, and forming the photodiode on the convex structure; or forming at least one of a P-type silicon layer, an N-type silicon layer, an I-type silicon layer and a transparent electrode of the photodiode into a convex structure.

In an alternative embodiment, the step of forming the portion of the gate insulating layer of the TFT corresponding to the photodiode into the convex structure includes: forming an organic insulating film with an inorganic insulating material; coating a photoresist with a protrusion onto the organic insulating film at a position corresponding to the photodiode; and dry-etching the organic insulating film coated with the photoresist so as to obtain the gate insulating layer having the convex structure.

Alternatively, the organic insulating material is etched at a rate greater than the photoresist. A ratio of an etching rate of the organic insulating material to that of the photoresist may be greater than 1 and less than 10.

In another alternative embodiment, the method includes: forming an integral structure of the drain electrode of the TFT and the reflective electrode layer, a portion of the integral structure corresponding to the photodiode being of a convex structure; and forming the photodiode on the convex structure.

In yet another alternative embodiment, the method includes steps of forming the reflective electrode layer having a convex structure on the drain electrode of the TFT, and forming the photodiode on the convex structure.

Alternatively, apart from the formation of the TFT and the photodiode, the method further includes steps of: forming a first passivation layer on the TFT and the photodiode; forming a bias electrode and a signal line on the first passivation layer, the bias electrode being connected to a transparent electrode through a via-hole in the first passivation layer; and forming a second passivation layer on the bias electrode and the signal line.

### Fourth Embodiment

The photoelectric conversion array substrate and its manufacturing method will be described hereinafter by taking a PIN-type photodiode as an example.

The PIN-type photodiode, as a critical component of the photoelectric conversion array substrate, may determine the absorption efficiency for the visible light beams. For the PIN-type photodiode, an intrinsic semiconductor layer (i.e., an I-type layer, e.g., an I-type silicon layer) at a very low doping concentration is grown between a P-type semiconductor layer (e.g., a P-type silicon layer) and an N-type semiconductor layer (e.g., an N-type silicon layer) each at a very high doping concentration. Due to a very small absorption coefficient of the I-type layer, an incident light beam may easily enter an interior of a material and fully absorbed by the material, so as to generate a large quantity of electron-hole pairs, so it has relatively high photoelectric conversion efficiency. In addition, the P-type layer and the N-type layer located at either sides of the I-type layer are very thin, and drifting time of photon-generated carriers is very short, so a response speed of the PIN-type photodiode is relatively high. In the case that the PIN-type photodiode is irradiated by light and the energy of the photoelectron is greater than an energy gap Eg, the electron on a valance band may absorb the energy of the photon and then jump to a conduction band, so as to form an electron-hole pair. For the electron-hole pair in a depletion layer, i.e., the intrinsic layer, the electron is drifted toward the N-type layer and the hole is drifted toward the P-type layer under the effect of a strong electric field, so as to form a photocurrent. The current may linearly change along with the optical power, so as to convert an optical signal into an electric signal.

The conventional PIN-type photodiode has a flat photosensitive surface, and in the case that the visible light beam is converted by the PIN-type photodiode into the electric signal, a scattering phenomenon of the visible light beam may usually occur, so the absorption efficiency for the visible light beam is relatively low and thereby the conversion efficiency of the photoelectric conversion array substrate for converting the visible light beam into the electric signal will be adversely affected.

In order to overcome the above-mentioned drawback, the present disclosure provides in this embodiment a photoelectric conversion array substrate and its manufacturing method. To be specific, the manufacturing method includes the following steps.

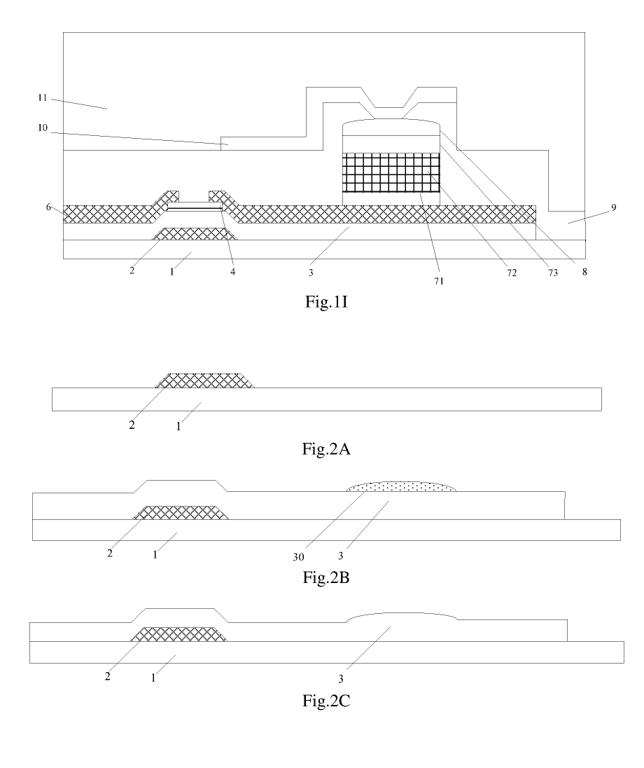

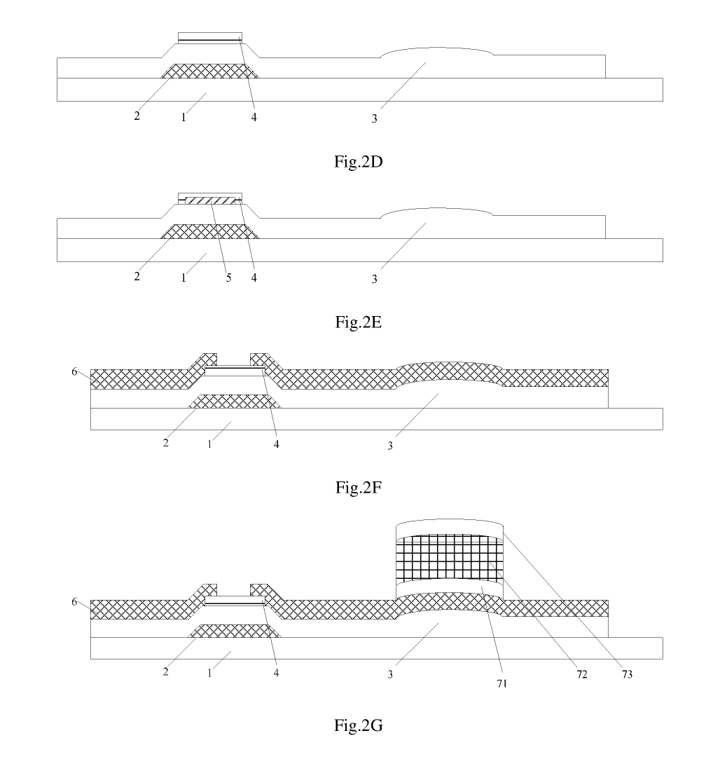

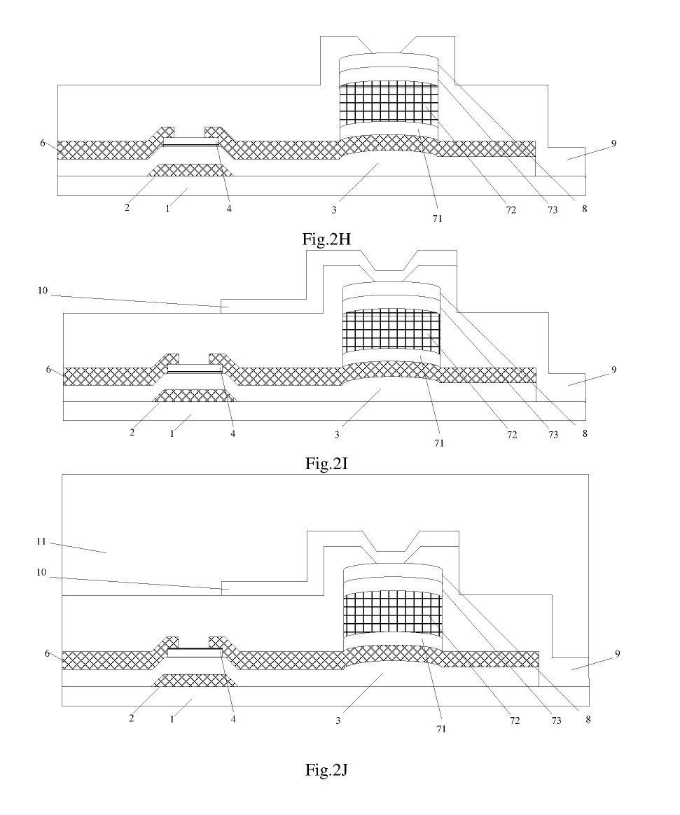

Step 1: as shown in FIG. 2A, providing a base substrate 1 and forming a pattern of a gate metal layer 2 on the base substrate 1. The base substrate 1 may be a glass or quartz substrate. To be specific, the gate metal layer 2 having a thickness of about 500 to 4000 Å may be deposited onto the base substrate 1 by sputtering or thermal evaporation. The gate metal layer 2 may be made of Cu, Al, Ag, Mo, Cr, Nd, Ni, Mn, Ti, Ta, W or an alloy thereof, and it may be of a single-layered structure, or a multi-layered structure e.g., Cu/Mo, Ti/Cu/Ti or Mo/Al/Mo. A photoresist may be applied onto the gate metal layer 2, and then exposed with a mask plate, so as to form a photoresist reserved region corresponding to a region where patterns of a gate line and a gate electrode are located, and a photoresist unreserved region corresponding to the other regions. Next, the photoresist may be developed, so as to remove the photoresist at the photoresist unreserved region and maintain a thickness of the photoresist at the photoresist reserved region. Then, the gate metal layer at the photoresist unreserved region may be fully etched off by an etching process and the remaining photoresist may be removed, so as to form the pattern of the gate metal layer 2.

Step 2: as shown in FIG. 2B, forming a gate insulating layer 3, and applying a photoresist with a semi-ellipsoidal shape at a position of the gate insulating layer 3 corresponding to the PIN-type photodiode. To be specific, the gate insulating layer 3 may be made of an organic material through spinning, and the organic material includes polyimide, polyvinyl alcohol, polyvinyl phenol, or polymethyl methacrylate.

Step 3: as shown in FIG. 2C, forming the gate insulating layer 3 having a semi-ellipsoidal protrusion. To be specific, the gate insulating layer 3 coated with the photoresist 30 may be etched by a dry-etching process, and alternatively, a ratio of an etching rate of the gate insulating layer to that of the photoresist may be 0.5 or within a range of 1 to 10. After the photoresist 30 has been fully etched off, it is able to acquire the gate insulating layer 3 having the semi-ellipsoidal protrusion. Alternatively, the gate insulating layer may be etched at a rate greater than the photoresist, so as to provide a convex surface of the protrusion with a greater curvature. In this way, it is able to provide the convex photosensitive surface of the photodiode formed on the protrusion with a greater curvature, thereby to converge the light beams in a better manner and improve the absorption efficiency for the visible light beams.

Step 4: as shown in FIG. 2D, forming a pattern of a semiconductor layer 4. To be specific, the semiconductor layer may be deposited onto the base substrate 1 obtained after Step 3. Next, a photoresist may be applied onto the semiconductor layer, and then exposed, so as to form a photoresist reserved region corresponding to a region where the pattern of the semiconductor layer 4 is located, and a photoresist unreserved region corresponding to the other regions. Next, the photoresist may be developed, so as to fully remove the photoresist at the photoresist unreserved region and maintain a thickness of the photoresist at the photoresist reserved region. Then, the semiconductor layer at the photoresist unreserved region may be fully etched off by an etching process, so as to form the pattern of the semiconductor layer 4.

Further, as shown in FIG. 2E, a pattern of a conductor layer 5 may be formed on the gate insulating layer 3, and then the semiconductor layer 4 may be formed for covering the conductor layer 5. In this way, it is able to reduce defects in a contact interface layer, thereby to improve the stability of the TFT. To be specific, the conductor layer 5 and the semiconductor layer 4 may be made of indium gallium zinc oxide (IGZO) at different oxygen contents.

Step 5: as shown in FIG. 2F, forming a pattern of a source/drain metal layer 6. To be specific, the source/drain metal layer 6 having a thickness of about 2000 to 4000 Å may be deposited onto the base substrate 1 obtained after Step 4 by magnetron sputtering, thermal evaporation or any other film-forming method. The source/drain metal layer may be made of Cu, Al, Ag, Mo, Cr, Nd, Ni, Mn, Ti, Ta, W or an alloy thereof, and it may be of a single-layered structure, or a multi-layered structure e.g., Cu/Mo, Ti/Cu/Ti or Mo/Al/Mo. Next, a photoresist may be applied onto the source/drain metal layer 6, and then exposed with a mask plate, so as to form a photoresist reserved region corresponding to regions where patterns of a source electrode, a drain electrode and reflective electrode layer are located, and a photoresist unreserved region corresponding to the other regions. Next, the photoresist may be developed, so as to fully remove the photoresist at the photoresist unreserved region and maintain a thickness of the photoresist at the photoresist reserved region. Then, the source/drain metal layer 6 at the photoresist unreserved region may be fully etched off by an etching process and the remaining photoresist may be removed, so as to form the source electrode, the drain electrode and the reflective electrode layer. The reflective electrode layer is connected to the drain electrode and arranged on semi-ellipsoidal protrusion.

Step 6: as shown in FIG. 2G, forming the PIN-type photodiode including an N-type silicon layer 71, an I-type silicon layer 72 and a P-type silicon layer 73. To be specific, the PIN-type photodiode is formed on the reflective electrode layer and the reflective electrode layer is formed on the semi-ellipsoidal protrusion, so the N-type silicon layer 71, the I-type silicon layer 72 and the P-type silicon layer 73 are each of a semi-ellipsoidal structure, i.e., a convex structure. In each pixel, the photosensitive surface of the PIN-type photodiode for receiving the light beams is a semi-ellipsoidal surface, so it is able to focus the light beams from the outside in a better manner and improve the absorption efficiency of the photodiode for the light beams, thereby to improve the conversion efficiency of the photoelectric conversion array substrate for converting the visible light beam into the electric signal.

Step 7: as shown in FIG. 2H, forming a transparent electrode layer 8 and a first passivation layer 9. To be specific, a transparent conductive layer having a thickness of about 300 to 1500 Å may be deposited onto the base substrate 1 obtained after Step 6 by sputtering or thermal evaporation. The transparent conductive layer may be made of indium tin oxide or indium gallium zinc oxide. Next, a photoresist may be applied onto the transparent conductive layer, and then exposed with a mask plate, so as to form a photoresist reserved region corresponding to a region where a pattern of the transparent electrode layer 8 is located, and a photoresist unreserved region corresponding to the other regions. Next, the photoresist may be developed, so as to fully remove the photoresist at the photoresist unreserved region and maintain a thickness of the photoresist at the photoresist reserved region. Then, the transparent conductive layer at the photoresist unreserved region may be fully etched off by an etching process, and the remaining photoresist may be removed, so as to form the transparent electrode layer 8.

Then, the first passivation layer 9 having a thickness of 2000 to 10000 Å may be deposited on the transparent electrode layer 8 by magnetron sputtering, thermal evaporation, plasma enhanced chemical vapor deposition (PECVD) or any other film-forming method. The first passivation layer may be made of an oxide, a nitride or an oxynitride. For example, the first passivation layer may be made of SiNx, SiOx, Si(ON)x or Al₂O₃, and it may be of a single-layered structure, or a double-layered structure consisting of a SiNx layer and an SiOx layer. A reactive gas corresponding to SiOx may be a mixture of SiH₄ and N₂O, and a reactive gas corresponding to the nitride or oxynitride may be a mixture of SiH₄, NH₃ and N₂ or a mixture of SiH₂Cl₂, NH₃ and N₂. Then, a pattern of the first passivation layer 9 provided with a via-hole may be formed through a single patterning process.

Step 8: as shown in FIG. 2I, forming a bias electrode layer 10. To be specific, a transparent conductive layer having a thickness of about 300 to 1500 Å may be deposited onto the base substrate 1 obtained after Step 7 by sputtering or thermal evaporation. The transparent conductive layer may be made of indium tin oxide, indium zinc oxide or any other transparent metal oxides. A photoresist may be applied onto the transparent conductive layer, and then exposed with a mask plate, so as to form a photoresist reserved region corresponding to a region where pattern of the bias electrode layer 10 is located, and a photoresist unreserved region corresponding to the other regions. Next, the photoresist may be developed, so as to fully remove the photoresist at the photoresist unreserved region and maintain a thickness of the photoresist at the photoresist reserved region. Then, the transparent conductive layer at the photoresist unreserved region may be fully etched off by an etching process, and the remaining photoresist may be removed, so as to form the pattern of the bias electrode layer 10. The bias electrode layer 10 is connected to the transparent electrode layer 8 through a via-hole in the first passivation layer 9.

Step 9: as shown in FIG. 2J, forming a second passivation layer 11. To be specific, organic resin having a thickness of about 4000 to 30000 Å may be applied onto the base substrate 1 obtained after Step 8 so as to form the second passivation layer 11 for protecting the bias electrode layer 10.

The photoelectric conversion array substrate may be obtained through the above-mentioned Steps 1 to 9. In this embodiment, the PIN-type photodiode of the photoelectric conversion array substrate includes a light absorption surface with a semi-ellipsoidal convex surface. Of course, the convex light absorption surface may be of any other shapes, e.g., a semi-spherical shape, as long as the convex surface may converge the light beams so as to improve the absorption efficiency of the photodiode for the visible light beams.

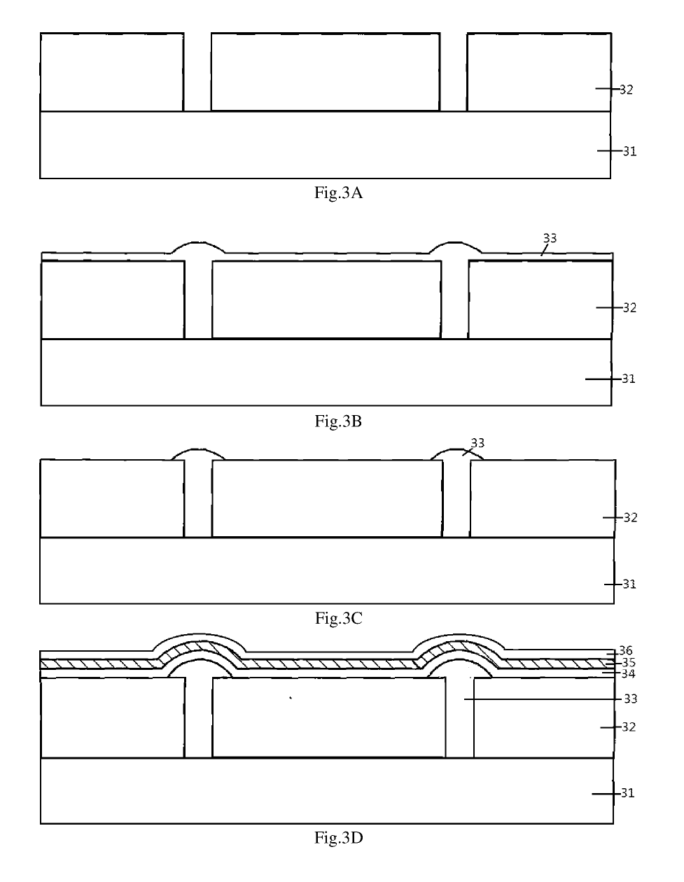

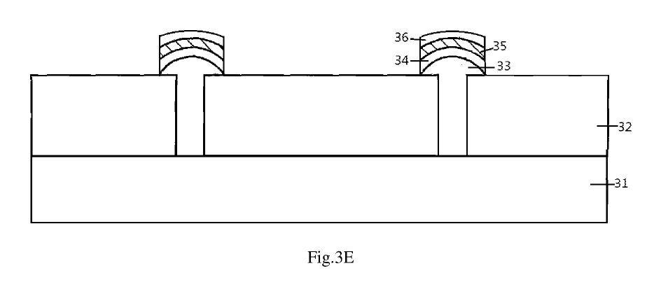

Further, the PIN-type photodiode with a convex photosensitive surface may also be formed on the base substrate with the TFT by an electroplating process. As shown in FIG. 3A, a base substrate 31 may be provided, and then a TFT and an insulating layer 32 covering the TFT may be formed on the base substrate 31. As shown in FIG. 3B, a metal electrode layer 33 with a protrusion may be formed on the insulating layer 32 by an electroplating process. As shown in FIG. 3C, the metal electrode layer 33 at the protrusion may be reserved while the metal electrode layer 33 at the other regions may be removed. As shown in FIG. 3D, an N-type silicon layer 34, an I-type silicon layer 35 and a P-type silicon layer 36 may be formed sequentially on the metal electrode layer 33. As shown in FIG. 3E, the N-type silicon layer 34, the I-type silicon layer 35 and the P-type silicon layer 36 at the protrusion may be reserved while those at the other regions may be removed, so as to form the PIN-type photodiode with the convex photosensitive surface. The PIN-type photodiode may be connected to the drain electrode of the TFT via the metal electrode layer 33.

In the case that the PIN-type photodiode with the convex photosensitive surface or the photoelectric conversion array substrate is applied to an X-ray detection device, it is able to improve the absorption efficiency of the X-ray detection device for the visible light beams, thereby to reduce an X-ray dose while ensuring the image quality.

The above are merely the preferred embodiments of the present disclosure. It should be appreciated that, a person skilled in the art may make further modifications and improvements without departing from the principle of the present disclosure, and these modifications and improvements shall also fall within the scope of the present disclosure.

1-12. (canceled)

13. A method for manufacturing a photoelectric conversion array substrate, comprising a step of forming on a base substrate a thin film transistor (TFT) and a photodiode connected to the TFT, wherein a photosensitive surface of the photodiode is a convex surface,
wherein the method further comprises:
forming at least one of a portion of the base substrate corresponding to the photodiode, a portion of a gate insulating layer of the TFT corresponding to the photodiode, a portion of a drain electrode of the TFT corresponding to the photodiode, and a portion of a reflective electrode layer of the photoelectric conversion array substrate corresponding to the photodiode into a convex structure, and forming the photodiode on the convex structure; or
forming at least one of a P-type silicon layer, an N-type silicon layer, an I-type silicon layer and a transparent electrode of the photodiode into a convex structure,
wherein the step of forming the portion of the gate insulating layer of the TFT corresponding to the photodiode into the convex structure comprises:
forming an organic insulating film with an organic insulating material;
coating a photoresist with a protrusion onto the organic insulating film at a position corresponding to the photodiode; and
dry-etching the organic insulating film coated with the photoresist so as to obtain the gate insulating layer having the convex structure.

14. The method according to claim 13, wherein the organic insulating material is etched at a rate greater than the photoresist.

15. The method according to claim 13, further comprising steps of:
forming an integral structure of the drain electrode of the TFT and the reflective electrode layer, a portion of the integral structure corresponding to the photodiode being of a convex structure; and
forming the photodiode on the convex structure.

16. The method according to claim 13, further comprising steps of:
forming the reflective electrode layer having a convex structure on the drain electrode of the TFT; and
forming the photodiode on the convex structure.

17. The method according to claim 13, further comprising a step of forming a PIN-type photodiode having a convex photosensitive surface on the base substrate provided with the TFT through an electroplating process.

18. The method according to claim 17, comprising steps of:
providing the base substrate;
forming the TFT and an insulating layer covering the TFT on the base substrate;
forming a metal electrode layer with a protrusion on the insulating layer through an electroplating process;
reserving the metal electrode layer at the protrusion and removing the metal electrode layer at the other regions;
forming an N-type silicon layer, an I-type silicon layer and a P-type silicon layer sequentially on the metal electrode layer at the protrusion; and
reserving the N-type silicon layer, the I-type silicon layer and the P-type silicon layer at the protrusion, and removing the N-type silicon layer, the I-type silicon layer and the P-type silicon layer at the other regions, so as to obtain the photodiode with a convex surface, the photodiode being connected to the drain electrode of the TFT via the metal electrode layer.

19-20. (canceled)

21. A method for manufacturing a photoelectric conversion array substrate, comprising a step of forming on a base substrate a thin film transistor (TFT) and a photodiode connected to the TFT, wherein a photosensitive surface of the photodiode is a convex surface,
wherein the method further comprises:
forming at least one of a portion of the base substrate corresponding to the photodiode, a portion of a gate insulating layer of the TFT corresponding to the photodiode, a portion of a drain electrode of the TFT corresponding to the photodiode, and a portion of a reflective electrode layer of the photoelectric conversion array substrate corresponding to the photodiode into a convex structure, and forming the photodiode on the convex structure; or
forming at least one of a P-type silicon layer, an N-type silicon layer, an I-type silicon layer and a transparent electrode of the photodiode into a convex structure, and
the method further comprises steps of:
forming an integral structure of the drain electrode of the TFT and the reflective electrode layer, a portion of the integral structure corresponding to the photodiode being of a convex structure; and
forming the photodiode on the convex structure.

22. A method for manufacturing a photoelectric conversion array substrate, comprising a step of forming on a base substrate a thin film transistor (TFT) and a photodiode connected to the TFT, wherein a photosensitive surface of the photodiode is a convex surface,
wherein the method further comprises:
forming at least one of a portion of the base substrate corresponding to the photodiode, a portion of a gate insulating layer of the TFT corresponding to the photodiode, a portion of a drain electrode of the TFT corresponding to the photodiode, and a portion of a reflective electrode layer of the photoelectric conversion array substrate corresponding to the photodiode into a convex structure, and forming the photodiode on the convex structure; or
forming at least one of a P-type silicon layer, an N-type silicon layer, an I-type silicon layer and a transparent electrode of the photodiode into a convex structure,
wherein the method further comprises:
forming a PIN-type photodiode having a convex photosensitive surface on the base substrate provided with the TFT through an electroplating process, and
wherein the method further comprises:
providing the base substrate;
forming the TFT and an insulating layer covering the TFT on the base substrate;
forming a metal electrode layer with a protrusion on the insulating layer through an electroplating process;
reserving the metal electrode layer at the protrusion and removing the metal electrode layer at the other regions;
forming an N-type silicon layer, an I-type silicon layer and a P-type silicon layer sequentially on the metal electrode layer at the protrusion; and
reserving the N-type silicon layer, the I-type silicon layer and the P-type silicon layer at the protrusion, and removing the N-type silicon layer, the I-type silicon layer and the P-type silicon layer at the other regions, so as to obtain the photodiode with a convex surface, the photodiode being connected to the drain electrode of the TFT via the metal electrode layer.
